(19) United States
(12) Patent Application Publication
(10) Pub. No.: US 2012/0180407 A1
(43) Pub. Date: Jul. 19, 2012

(54) ROOF TRUSS KIT TO ENABLE SUPPORT OF SOLAR PANELS ON ROOF STRUCTURES

(76) Inventors: Kyle J. Rees, Woodbridge (CA); Michael Jeske, Toronto (CA)

(21) Appl. No.: 13/212,931

(22) Filed: Aug. 18, 2011

Related U.S. Application Data
(60) Provisional application No. 61/432,251, filed on Jan. 13, 2011.

(30) Foreign Application Priority Data
Feb. 1, 2011 (CA) 2730484

(51) Int. Cl. E04D 13/18; E04B 1/38; H01L 31/18

(52) U.S. Cl. 52/173.3; 29/890.033; 52/223.1

(57) ABSTRACT

A truss reinforcing retrofit kit and method for strengthening an existing roof structure. The kit includes a tensile member, two couplings attached to the ends of the tensile member, and a king post tensioning system. The tensile member is coupled to the ends of the roof structure using the couplings. The king post tensioning system is positioned between the roof structure and the middle of the tensile member. Tension is increased within the tensile member so as to put the tensile member and the king post tensioning system under strain when there is an additional load on the roof structure in addition to a pre-existing dead load. For example, the additional load may be caused by one or more solar panels mounted on the roof structure. Alternatively, the tension might put the tensile member and the king post tensioning system under strain when the roof structure is subject only to the pre-existing dead load.

This application is a non-provisional application claiming priority to U.S. Provisional Application No. 61/432,251 filed Jan. 13, 2011, entitled “Roof Truss Kit To Enable Support of Solar Panels on Roof Structures.” This application also claims priority under 35 U.S.C. 119 to Canadian Patent Application No. 2,370,484 filed Feb. 2, 2011, entitled “Roof Truss Kit To Enable Support of Solar Panels on Roof Structures.”

### STATEMENT REGARDING FEDERALLY SPONSORED RESEARCH OR DEVELOPMENT

Not applicable.

### TECHNICAL FIELD

This specification relates to apparatus and methods for mounting solar panels on new or existing roof structures, or for strengthening existing roof structures so that they can support increased loads, for example loads created by mounting solar panels on the roof or installing auxiliary mechanical equipment or other objects to be placed on a rooftop.

### BACKGROUND

The following discussion is not an admission that anything discussed below is common general knowledge or citable as prior art.

Rooftop mounted solar panels have been developed for use with flat roofs as often used with commercial and industrial buildings. The solar panels allow the owner to collect and use solar generated power themselves, or to sell solar generated power to energy distributors. Either way, the use of solar panels can improve the quality of the environment by reducing reliance on other energy sources.

In many cases, it would be desirable to mount solar panels onto the roof of an existing building. In one system, solar panels are mounted on rooftops using a molded plastic mounting structure partially filled with ballast such as gravel or concrete blocks. The ballast weighs down the mounting structure and prevents the solar panel from being blown off the roof. Other mounting systems may use metal structures. In some cases the weight of the solar panel and the mounting structure may act alone as the ballast. Unfortunately, the additional weight of the solar panels, the mounting structure, and any ballast may exceed the design capacity of the roof structure, which inhibits the use of roof top solar panels.

### SUMMARY

The following is intended to introduce the reader to the detailed description to follow, and not to limit or define any claimed invention.

While it might be possible to reduce the weight of roof mounted solar panels or their mounting structures, or to erect new buildings with roof structures that have higher load capacities, these options do not allow mounting of currently commercially viable solar panel and mounting systems on many existing roof structures. As an alternative to this approach, this specification describes an apparatus and method to strengthen an existing roof structure to enable it to support an increased load, for example as required to support solar panels and their mounting systems.

Commercial and industrial buildings often have flat rooftops with standardized roof structures made with open web steel joist trusses. It is possible to weld or bolt additional members to an existing truss in order to increase its strength, but this would intrude on commercial or industrial operations within the building. For example, a large warehouse style retail store may be open 24 hours a day and have rows of shelving filled with inventory throughout the store. Installing large truss members on the roof structure would likely require the store to be closed to customers and inventory relocated due to the need for scaffolding and risk of material falling from overhead, causing a loss in profits.

An apparatus described herein for mounting solar panels on an existing roof structure comprises mounting structures for supporting the solar panels on the roof structure and a retrofit kit for strengthening an existing roof structure. The retrofit kit is adapted in particular for use with open web steel joist trusses. The kit includes a flexible tensile member, such as a cable, couplings attached to the ends of the tensile member, and a king post tensioning system. The couplings and king post tensioning system are adapted to be fitted onto the ends and middle of the lower cord of a truss. The tensile member and king post tensioning system may be held in place by interference fits and tension in the cable, optionally without bolting or welding them to the truss. The tensile member and king post tensioning system are strained when the roof structure is loaded by the mounting structures and the solar panels, and so contributes to resisting those loads. The retrofit kit may also be used for increasing the capacity of a roof to accommodate other loads.

The apparatus may also include an end stiffener sister system for reinforcing an end of the roofing structure, and in particular, for reinforcing an end web of an open web steel joist. Furthermore, there may be two end stiffener sister systems, namely, one at each end of the roofing structure.

The end stiffener sister system is attached to the end web for strengthening the open web steel joist, for example, to support additional loads on the open web steel joist. More particularly, the end stiffener sister system is strained when the roof structure is loaded by the mounting structure and the solar panel, and so contributes to resisting those loads. The end stiffener sister system may include one or more stiffening members clamped to the end web, for example, using grub bolt clamps.

A method is described herein for increasing the strength of an existing roof truss, for example to enable mounting solar panels on an existing roof structure. The method comprises coupling the ends of the tensile member to the ends of the lower cord of a previously installed truss. A king post tensioning system is placed at about the middle of the lower cord of the truss, extending downwards to the tensile member. The tensile member is preferably tensioned before mounting the solar panels on the roof structure. The tensile member and the king post tensioning system are configured to be under strain when there are loads on the roof structure caused by mounting the solar panel on the roof structure. The solar panels are preferably mounted in ballasted solar panel mounting structures. The method may also be used for purposes other than mounting solar panels to an existing roof structure.

The method may also include installing an end stiffener sister system on an end of the roof structure, and in particular, to an end web of an open web steel joist. The tensile member is preferably tensioned before installing the end stiffener sister system.

### BRIEF DESCRIPTION OF THE DRAWINGS

FIG. 1 is a side elevation view of a retrofit kit for strengthening an existing roof structure to enable mounting of one or more solar panels to the existing roof structure;

FIG. 2 is a magnified side elevation view of an end of a tensile member of the retrofit kit of FIG. 1;

FIG. 3 is a magnified side elevation view of a king post tensioning system of the retrofit kit of FIG. 1;

FIG. 4 is a magnified side elevation view of another end of the tensile member of the retrofit kit of FIG. 1;

FIG. 5 is a perspective view of a coupling of the retrofit kit of FIG. 1;

FIG. 6 is an end elevation view of the coupling hooked on to a lower chord of the roof structure;

FIG. 7 is an end elevation view of the king post tensioning system connected to the lower chord of the roof structure;

FIG. 8 is a cross-sectional view of a guy wire dead end attached to the end of the tensile member shown in FIG. 2;

FIG. 9 is a partial side elevation view of an end stiffener sister system connected to the roof structure;

FIG. 10 is a partial end elevation view of an upper grub bolt clamp securing the end stiffener sister system to the roof structure;

FIG. 11 is a side view of the upper clamp of FIG. 10;

FIG. 12 is a side view of a lower clamp for securing the end stiffener sister system to the roof structure; and

FIG. 13 is a flow chart depicting a method of mounting a solar panel on an existing roof.

### DETAILED DESCRIPTION

In the drawings and description that follow, like parts are typically marked throughout the specification and drawings with the same reference numerals. The drawing figures are not necessarily to scale. Certain features of the disclosure may be shown exaggerated in scale or in somewhat schematic form and some details of conventional elements may not be shown in the interest of clarity and conciseness. The present disclosure is susceptible to embodiments of different forms. Specific embodiments are described in detail and are shown in the drawings, with the understanding that the present disclosure is to be considered an exemplification of the principles of the disclosure, and is not intended to limit the disclosure to that illustrated and described herein. It is to be fully recognized that the different teachings of the embodiments discussed below may be employed separately or in any suitable combination to produce desired results. In the following discussion and in the claims, the terms “including” and “comprising” are used in an open-ended fashion, and thus should be interpreted to mean “including, but not limited to . . . ”. The various characteristics mentioned above, as well as other features and characteristics described in more detail below, will be readily apparent to those skilled in the art upon reading the following detailed description of the embodiments, and by referring to the accompanying drawings.

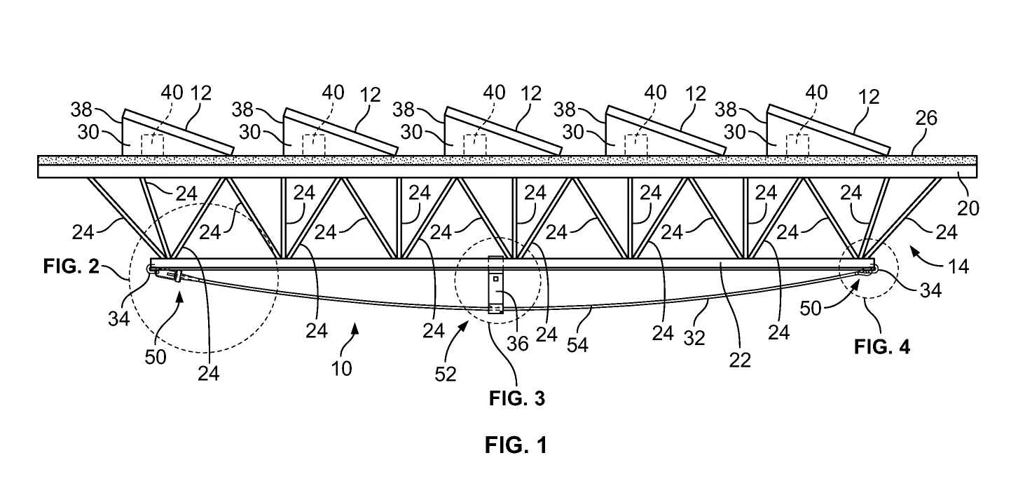

Referring to FIG. 1, illustrated therein is a retrofit kit 10 for reinforcing an existing roof structure 14. The kit 10 is used in FIG. 1 to enable mounting one or more solar panels 12 to the existing roof structure 14. The roof structure 14 includes a truss, and in particular, an open web steel joist. The truss includes an upper chord 20, a lower chord 22 and a plurality of web members 24 connecting the upper chord 20 and the lower chord 22. The kit 10 may also be adapted for use with other roof structures, such as other trusses, girders, beams, and the like. The solar panels 12 are mounted on top of the roof structure 14, and in particular, on a flat rooftop 26, which may be covered with gravel, asphalt, or other materials. The rooftop 26 is typically supported by a plurality of roof structures 14 spaced laterally apart from each other.

The kit 10 includes a tensile member 32, adapted to extend along the length of the lower cord 22 of the roof structure 14, two couplings 34 for coupling the tensile member 32 to the roof structure 14, and a king post tensioning system 36, to be positioned between the roof structure 14 and the tensile member 32.

The retrofit kit 10 is used in FIG. 1 with one or mounting structures 30 for supporting the solar panels 12 on the roof structure 14. In particular, a mounting structure as shown in U.S. Patent Application No. 61/362,049, which is incorporated herein in its entirety for all purposes, may be used.

Each mounting structure 30 supports one or more of the solar panels 12 on the roof structure 14. In FIG. 1, there are five solar panels 12 supported on the area of the rooftop 26 immediately above the roof structure 14 by five corresponding molded plastic mounting structures 30. There may be an array of solar panels 12 and mounting structures 30 extending in rows and columns along the rooftop 26. According to other mounting systems, there may be any number of solar panels 12 and mounting structures 30 on the rooftop 26. For example, there may be one mounting structure 30 that supports multiple solar panels.

Each mounting structure 30 includes a housing 38. The housing 38 shown is generally made of injection molded plastic. The housing is shaped to hold the solar panel at a desirable inclination to the sun. Alternatively, the housing 38 may be constructed from other materials such as other plastics, metals, composites, and the like.

The housing 38 may have an internal chamber shaped to receive ballast 40 for weighing down and stabilizing the mounting structure 14 and the solar panel 12 supported thereon. The ballast 40 may be gravel, concrete blocks, and the like. Alternatively, the mounting structure 14 may be of a type installed without ballast.

The weight of the solar panel 12, the mounting structure 30, and possibly the ballast 40 increases the dead load on the roof structure 14. The existing roof structure 14 has a specific load capacity and in many cases placing one or more solar panels 12, mounting structures 30, and ballasts 40 on the rooftop 26 would exceed that load capacity. As such, it is necessary to strengthen the rooftop structure 14. Accordingly, the tensile member 32, couplings 34 and king post tensioning system 36 are generally configured and installed to increase the loading capacity of the roof structure.

The tensile member 32 has two ends 50 and a middle portion 52. In the kit 10 of FIG. 1, the tensile member 32 includes a continuous cable 54 extending between the two ends 50 and below the lower chord 22. For example, the cable 54 may be a guy wire made from braided stainless steel wire, or another suitable material.

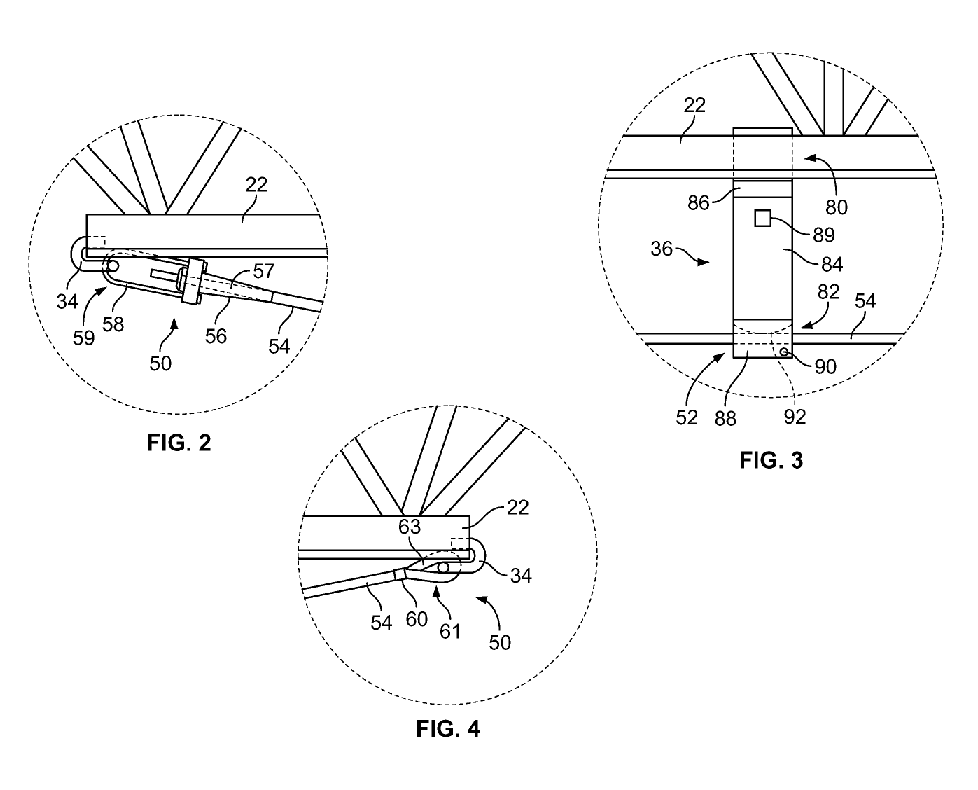

The ends 50 of the tensile member 32 are coupled to the roof structure 14 using the couplings 34. In particular, the two couplings 34 are attached to the ends 50 of the tensile member 32 and are then coupled to the lower cord 22 of the roof structure 14. For example, referring to FIG. 2, one end 50 of the tensile member 32 has an automatic guy wire dead end 56 that clamps on to an end portion 57 of the cable 54. An anchor bail 58 is coupled to the dead end 56, which forms a loop 59 for attachment to one of the couplings 34. The automatic guy wire dead end 56 provides a means for adjusting the tensile member 32 to the length of the lower chord 22. The length of the lower chord 22 may differ from joist to joist. The automatic guy wire dead end 56 also tends to pretension the cable 54 before the cable 54 is finally tensioned using the king post tensioning system 36.

Referring to FIG. 4, the other end 50 of the tensile member 32 has a loop 61 formed by an end portion 63 of the cable 54 looping backwards on itself and a ring clamp 60 that secures the end portion 63 to the rest of the cable 54. The other coupling 34 is attached to the tensile member 32 through the loop 61.

As described above, the couplings 34 are attached to the ends 50 of the tensile member 32 and are used to couple the tensile member 32 to the roof structure 14. In the kit 10 of FIG. 1, the couplings 34 are hooks, which engage the ends of the lower chord 22 as will be described below.

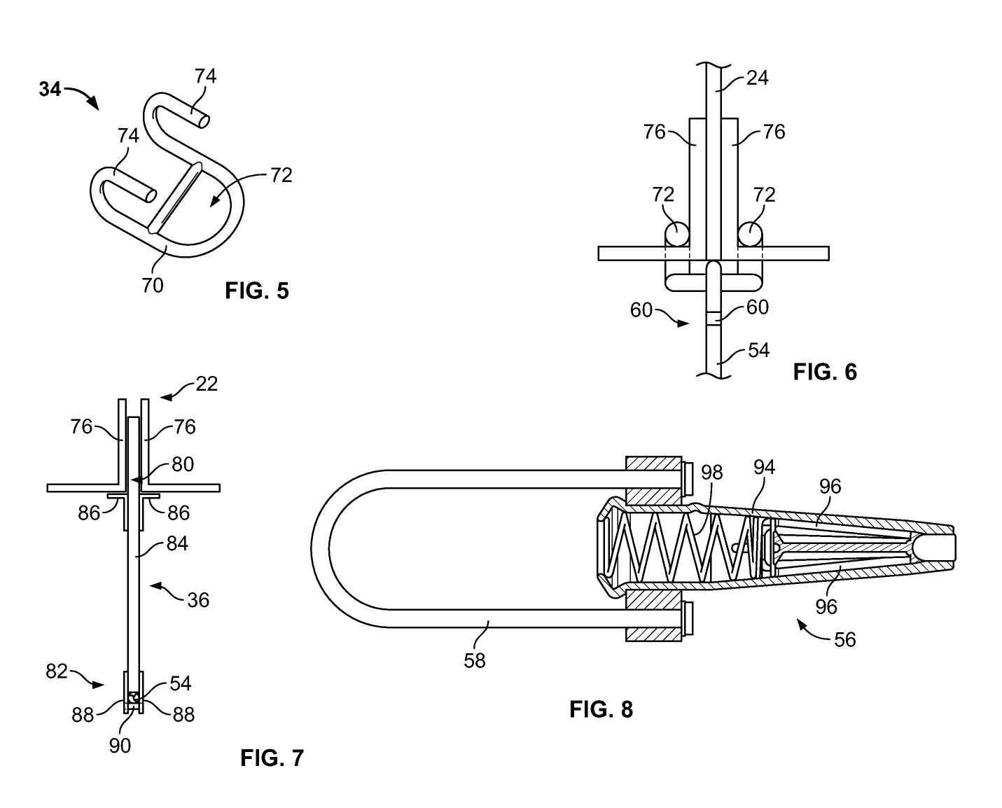

Referring to FIG. 5, each coupling 34 has a base 70 with an opening 72 for attachment to the ends 50 of the tensile member 32. In particular, the loops 59 and 61 formed at either end 50 of the tensile member 32 extend through the opening 72 for attachment to each coupling 34.

Two prongs 74 extend rearwardly from the base 70 and bend upwardly and then forwardly to form two U-shaped hooks for engaging the lower chord 22 of the roof structure 14 as shown in FIGS. 2 and 6. In particular, referring to FIG. 6, the lower chord 22 is formed by two spaced apart L-shaped members 76 with the web members 24 of the truss secured therebetween. The prongs 72 engage the upper horizontal surfaces of the L-shaped members 76 and are supported therefrom. Tension within the tensile member 32 pulls the prongs 72 against the ends of the lower chord 22.

The couplings 34 tend to facilitate easy attachment of the tensile member 32 to the lower chord 22, particularly when the L-shaped members 76 of the lower cord 22 are uneven in length. In which case, the couplings 34 might be attached to the roof structure at skewed angles relative to the lower chord. When this is the case, the openings 72 within each coupling 34 allow the ends of the cable 54 to shift laterally so as to center the cable 54 along the lower chord 22 while the hooks formed by the two prongs 74 secure the cable 54 in place. Furthermore, the two prongs 74 of the coupling 34 are located on either side of the central vertical portion of the lower chord 22, which tends to prevent the couplings 34 from sliding sidewise or spreading relative to the central vertical portion, and thereby prevents the couplings 34 from falling off the sides of the L-shaped members 76.

Referring to FIGS. 1, 3 and 7, the king post tensioning system 36 is placed between the middle portion 52 of the tensile member 32 and the roof structure 14. In particular, the king post tensioning system 36 has an upper portion 80 that can be fitted to the lower cord 22 of the roof structure 14, and a lower portion 82 that bears against the middle portion 52 of the tensile member 32.

The king post tensioning system 36 includes a plate 84 extending from the upper portion 80 to the lower portion 82. When installed, the upper portion 80 of the plate 84 slides between the two L-shaped members 76 of the lower chord 22 (shown in FIG. 7). The king post tensioning system 36 also includes two flanges 86 on either side of the plate 84 adjacent to the upper portion 80. The flanges 86 position the king post tensioning system 36 relative to the lower chord 22 and prevent the plate 84 from sliding all the way up through the gap between the two L-shaped members 76.

The king post tensioning system 36 also includes two side plates 88 attached to the lower portion 82 of the plate 84. The side plates 88 extend below the plate 84 and define a channel for receiving the cable 54. Tension within the tensile member 32 tends to hold the cable 54 firmly against a lower end 92 of the plate 84, and applies an upward force. The upward force is transmitted through the king post tensioning system 36, and to the lower chord 22 via the flanges 86. Tension within the tensile member 32 thus forces the king post tensioning system 36 upward against the roof structure 14 and, in combination with the fit between the king post tensioning system 36 and the lower cord 22, keeps the king post tensioning system 36 in place.

While tension within the tensile member 32 generally holds the cable 54 against the lower end 92 of the plate 84, the side plates 88 also have an aperture for receiving a safety pin 90, which helps retain the tensile member 32 within the channel.

As shown in FIG. 3, the lower end 92 of the plate 84 may have a convex shape. The convex shaped lower end 92 tends to engage the cable 54 along a smooth continuous surface. This reduces stress within the cable 54 in comparison to a discontinuous surface, which might otherwise introduce point loads and other stress concentrations.

The king post tensioning system 36 has a height that positions the middle portion 52 of the tensile member 32 lower than the ends 50. As such, tension within the tensile member 32 helps resist loads bearing downwards on the roof structure 14, as will be described below.

Generally, the tensile member 32 and the king post tensioning system 36 act as additional load bearing members that cooperate with the existing roof structure 14. The tensile member 32 is generally under tensile strains, while the king post tensioning system 36 is generally under compressive strains. Furthermore, the tensile member 32 and the king post tensioning system 36 are typically configured to be under strain at least when the solar panel 12, mounting structure 30, and any ballast 40 cause loads on the roof structure 14, in addition to any pre-existing dead load associated with the roof structure 14. In other words, the tensile member 32 and the king post tensioning system 36 at least partially bear the weight of the solar panel 12, mounting structure 30, and possibly ballast 40.

The tensile member 32 and the king post tensioning system 36 may also be configured to be under strain when the solar panel 12, mounting 30 structure 30, and ballast 40 are not yet mounted on the roof structure 14. In this case, the tensile member 32 and the king post tensioning system 36 tend to partially bear the weight of the pre-existing dead load on the roof structure 14, for example, prior to mounting the solar panel 12 thereon. In this configuration, the tensile member 32 and the king post tensioning system 36 bear a larger portion of the total loading, including the weight of the solar panel 12, mounting structure 30, any ballast 40, and other live loads that might be on the roof structure 14.

Increasing the amount of strain on the tensile member 32 and the king post tensioning system 36 generally provides a corresponding increase in strength and load bearing capacity subject to not exceeding the capacity of the king post tensioning system 36 and tensile member 32. Furthermore, the amount of tension in the tensile member 32 generally corresponds to the amount of strain within the tensile member 32 and the king post tensioning system 36. As such, the amount of tension may be selected to increase the strength of the roof structure 14 as required for a particular load, for example, as required to support the weight of selected solar panels 12, mounting structures 30, and ballast 40 if any.

When installing the retrofit kit 10, the amount of tension in the tensile member 32 is generally set by first adjusting the length of the tensile member 32 to take up excess slack, and then placing the king post tensioning system 36 between the tensile member 32 and the lower chord 22 so as to provide the desired amount of tension.

The tensile member 32 may have an adjustable length for adjusting the length or tension in the tensile member 32. For example, referring to FIGS. 2 and 8, the automatic guy wire dead end 56 is attached to the cable 54 for adjusting the length of the cable 54. In particular, referring to FIG. 8, the dead end 56 includes a shell housing 94, a plurality of internal jaws 96 slidably mounted within the shell housing 94, and a spring 98. The housing 94 has a central frustoconical opening for the receiving the cable 54 therethrough. The jaws 96 are spaced apart circumferentially within the frustoconical opening and form a central aperture therebetween for receiving the cable 54. The spring 98 generally biases the jaws 96 toward the tip of the frustoconical opening, which forces the jaws 96 radially inward in order to clamp onto the cable 54.

During installation, the cable 54 is pulled through the housing 94 and the jaws 86 slide backwards while compressing the spring 98. While sliding backwards, the jaws 96 eventually disengage the cable 54 so that the cable can be pulled through the housing without restriction from the jaws 96. Once the cable 54 has been pulled to a desired position or tension, the cable 54 is released and the spring 98 forces the jaws 96 back toward the tip of the frustoconical opening, which causes the jaws 96 to come together and engage the cable 54. The jaws 96 generally hold the cable 54 securely in place so as to provide the tensile member 32 with a desired length, and possibly at a desired tension.

Once the length of the tensile member 32 has been adjusted, and the two ends of the tensile member 32 have been connected to the lower chord 22, the king post tensioning system 36 is put in place so as to increase or create tension within the tensile member 32. One way of putting the king post tensioning system 36 into place is to pivot the king post tensioning system 36 from a horizontal orientation to a vertical orientation. More particularly, a lever (not shown) such as a Johnson bar may be inserted into a square hole 89 (shown in FIG. 3) within the plate 84 in order to pry and pivot the king post tensioning system 36 into place while tensioning the tensile member 32. While rotating the king post tensioning system 36 into place, the convex shaped lower end 92 generally cams along the cable 54.

Alternatively, the amount of tension in the tensile member 32 may be adjusted using another type of tensioner. For example, the king post tensioning system 36 may have an adjustable height for adjusting the amount of tension in the tensile member 32.

The configuration of the retrofit kit 10 tends to increase the strength of the roof structure 14 with minimal onsite fabrication of parts, and without modifying the roof structure 14 itself. In particular, the couplings 34 merely hook on to the ends of the lower chord 22, and the king post tensioning system 36 merely abuts the bottom of the lower chord 22. No holes, apertures, welds, or other structural modifications are necessary. This is beneficial because such structural modifications would increase the labour costs of the retrofit and might weaken the roof structure 14, for example, by introducing stress concentrations. Further, the tensile member can be brought into position on a spool and rolled out across the lower cord 22. Accordingly, no long and rigid pieces need to be moved through the building or supported during assembly.

Notwithstanding the above, the couplings 34 and the king post tensioning system 36 might alternatively be connected to the roof structure 14 by making structural modifications. For example, the couplings 34 and/or king post tensioning system 36 may be fastened to the roof structure using fasteners, such as bolts, rivets, and the like.

Making the tensile member 32 from a continuous cable 54 tends to provide greater strength in comparison to using a plurality of interconnected members connected between the two ends of the lower chord 22. In particular, the continuous cable 54 does not have any additional joints, which might otherwise form stress concentrations that would weaken the tensile member 32. Notwithstanding the above, the tensile member 32 may be formed from a plurality of interconnected members, which may include rigid members such as beams and rods, flexible members such as cables, and the like.

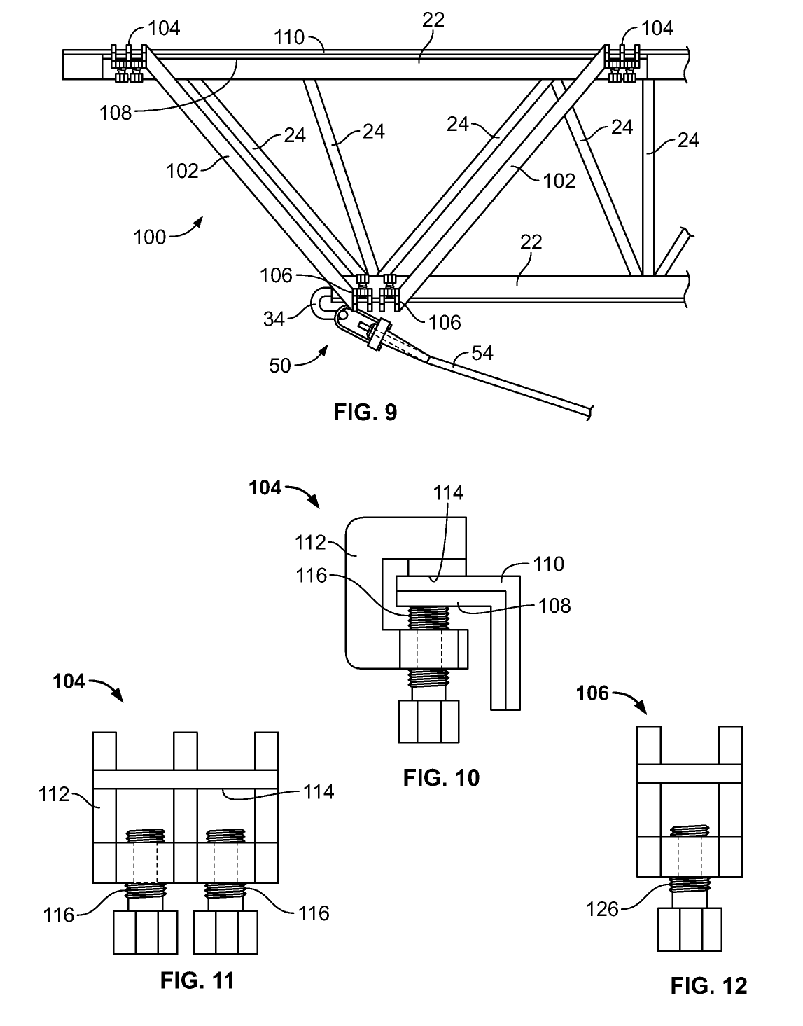

Referring now to FIG. 9 the retrofit kit 10 may also include one or more end stiffener sister systems 100 connectable the roof structure 14. Each end stiffener sister systems 100 is generally located at the ends of the roof structure 14 so as to reinforce or strengthen the roof structure 14 proximal to the ends 50 of the tensile member 32. End stiffener sister systems 100 may be particularly useful when the roof structure 14 extends over a large span, and the tensile member 32 would be under a large force. This large force would be transmitted to the ends of the roof structure 14, and the end stiffener sister systems 100 would help bear the load caused by this force.

The end stiffener sister system 100 generally comprises a plurality of additional truss end reinforcing members connectable to the roof structure 14 such as stiffening members 102. In FIG. 9, there are two stiffening members 102 extending diagonally in opposite directions between the upper chord 20 and the lower chord 22. Alternatively, the end stiffener sister system 100 may include one or more stiffening members 102 extending diagonally or vertically between, or beside and along, the upper and lower chords 20 and 22.

The stiffening members 102 are secured to the roof structure 14 using grub bolt clamps 104 and 106. In particular, there are two upper grub bolt clamps 104 and two lower grub bolt clamps 106 for securing the ends of the stiffening members 102 to the upper and lower chords 20 and 22 respectively. The grub bolt clamps 104 and 106 shown in FIG. 8 are c-clamps. Alternatively, other types and numbers of clamps may be utilized.

As shown, the end stiffener sister system 100 also includes an angle bar 108 for indirectly securing the stiffening members 102 to the upper chord 20. The angle bar 108 is attached to the upper ends of the two stiffening members 102, for example using welds, rivets, or another suitable fastener. The upper grub bolt clamps 104 secure the angle bar 108 to a corresponding angle bar 110 on the upper chord 20. In particular, the upper clamps 104 clinch the horizontal portion of each angle bar 108 and 110 together as shown in FIG. 10.

As shown in FIG. 11, each upper grub bolt clamp 104 includes a body 112 having a clamping surface 114, and two grub bolts 116 threaded into corresponding threaded apertures within the body 112. The two grub bolts 116 are located side-by-side and can be screwed into the body 112 so as to clinch the angle bars 108 and 110 between the head of the grub bolts 116 and the clamping surface 114.

The lower ends of the stiffening members 102 are directly secured to the lower chord 22 using the lower grub bolt clamps 106. In particular, the lower end of each stiffening member 102 is attached to one of the lower grub bolt clamps 106 for securing the stiffening member 102 to the lower chord 22, and in particular, to the horizontal portion of one of the L-shaped members 76.

One of the lower grub bolt clamps 106 is shown in FIG. 12. The lower grub bolt clamps 106 are generally similar to the upper grub bolt clamps 104, except that there is only one grub bolt 126 instead of two grub bolts 116.

While FIG. 9 illustrates one possible configuration for securing the stiffening members 102 to the roof structure 14, alternatively, the stiffening members 102 may be directly or indirectly secured to the roof structure 14, for example using one or more clamps or another type of removable fastener such as bolts, screws and the like. Furthermore, the stiffening members 102 may be directly or indirectly secured to the roof structure using permanent fasteners, such as welds, rivets, and the like.

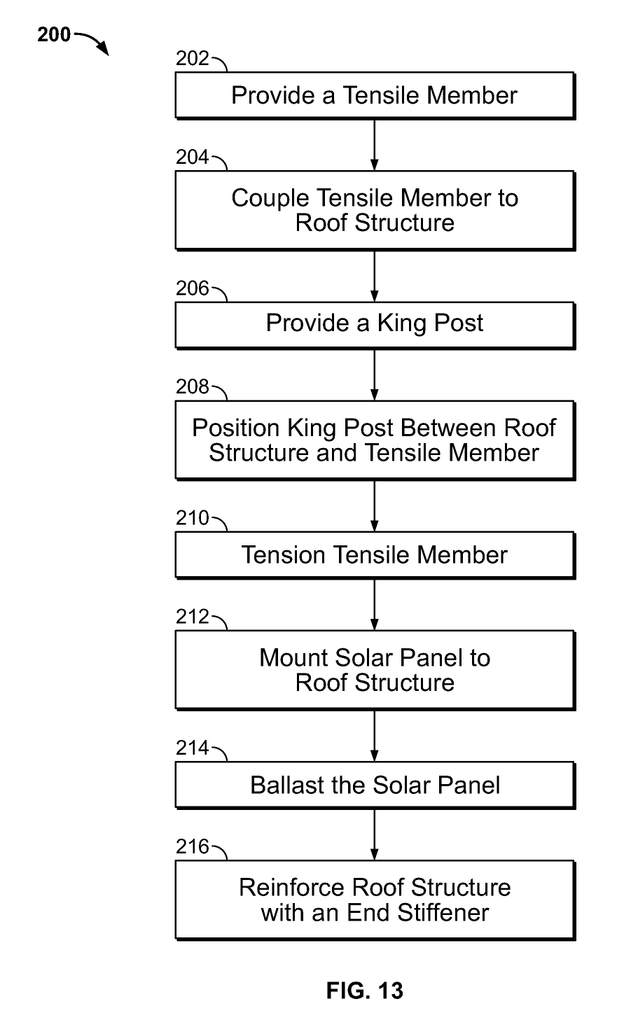

Referring now to FIG. 13, there is a method 200 of mounting a solar panel on an existing roof structure, such as the roof structure 14. The method 200 includes steps 202-216.

Step 202 includes providing a tensile member having two ends and a middle portion, such as the tensile member 32.

Step 204 includes coupling the tensile member to the roof structure such that the tensile member extends along the roof structure. For example, the two ends of the tensile member may be coupled to the roof structure using the couplings 34.

Step 206 includes providing a king post tensioning system, such as the king post tensioning system 36.

Step 208 includes positioning the king post tensioning system between the roof structure and the middle portion of the tensile member.

Step 210 includes tensioning the tensile member. For example, Step 206 of positioning the king post tensioning system 36 between the roof structure 14 and the tensile member 32 might create or increase tension within the tensile member 32. Furthermore, the length of the tensile member may be adjusted to create or increase tension. Furthermore still, one end connection, such as the guy wire dead end 56, may be adjusted to create or increase tension.

Step 212 includes mounting the solar panel on the roof structure. For example, the mounting structure 30 may be placed on the rooftop and the solar panel may be mounted thereto.

Generally, the tensile member and the king post tensioning system are configured to be under strain when there are loads on the roof structure caused by mounting the solar panel on the roof structure. In particular, Step 210 generally provides sufficient tension to strain both the tensile member and the king post tensioning system when the solar panel is mounted on the roof structure. Step 210 might also provide sufficient tension to strain both the tensile member and the king post tensioning system when there is only a pre-existing dead load on the roof structure, for example, prior to mounting the solar panel on the roof structure. Step 210 of tensioning the tensile member might occur before step 212 of mounting the solar panel on the roof structure because the roof structure might not have a sufficient load capacity to support the solar panel. Alternatively, step 212 may occur before, after, or contemporaneously with any of the preceding steps.

Step 214 includes ballasting the solar panel on the roof structure. For example, the ballast 40 may be positioned within the mounting structure 30 so as to weigh down the mounting structure and prevent the solar panel 12 from being blown off the roof. Step 214 may be omitted, for example, when the mounting structure is of a type installed without ballast. In that case, step 212 may be replaced by another appropriate mounting step.

Step 216 includes reinforcing the roof structure proximal to the ends of the tensile member. For example, the roof structure may be reinforced using the end stiffener sister system 100, and the end stiffener sister system may be located adjacent to one of the ends of the tensile member. Step 216 may occur before, after, or contemporaneously with any of the preceding steps. Furthermore, step 216 may be omitted, for example, when reinforcement is not necessary, which may be the case when the roof structure extends over a relatively short span.

The retrofit kit 10 and the method 200 may be used to strengthen an existing roof structure in order to support rooftop loads caused by objects other than solar panels. For example, the retrofit kit 10 and the method 200 may be used to strengthen an existing roof structure in order to support a rooftop mounted HVAC unit, a ventilator, a refrigeration unit, a rooftop mounted wind turbine, rooftop mounted industrial equipment, or other rooftop loads. In such embodiments, the retrofit kit 10 might not be used with a mounting structure 30, and the method might not include step 212 of mounting the solar panel on the roof structure.

While the above description provides examples of one or more apparatus, methods, or systems, it will be appreciated that other apparatus, methods, or systems may be within the scope of the present description as interpreted by one of skill in the art.

What is claimed is:

1. An apparatus for mounting a solar panel on an existing roof structure comprising:
a) a mounting structure for supporting the solar panel on the roof structure; and
b) a retrofit kit comprising:
i) a tensile member having two ends and a middle portion;
ii) two couplings attached to the ends of the tensile member, the couplings being couplable to the roof structure such that the tensile member extends along the roof structure; and
iii) a king post tensioning system having an upper portion connectable to the roof structure, and a lower portion connectable to the middle portion of the tensile member;
wherein the tensile member and the king post tensioning system are configured to be under strain when there are loads on the roof structure caused by the mounting structure and the solar panel.

2. The apparatus of claim 1, further comprising additional truss end reinforcing members.

3. The apparatus of claim 1, wherein the tensile member is a continuous cable.

4. The apparatus of claim 3, wherein the king post tensioning system has a convex lower end shaped to engage the cable.

5. The apparatus of claim 1, wherein the upper portion of the king post tensioning system is shaped to fit within a gap within the roof structure so as to connect the king post tensioning system to the roof structure.

6. The apparatus of claim 1, wherein the couplings include hooks attached to the ends of the tensile member, each of the hooks configured to hook onto the roof structure.

7. The apparatus of claim 1, wherein the mounting structure includes a housing shaped to receive ballast.

8. A method for mounting a solar panel on an existing roof structure, the method comprising:
a) providing a tensile member having two ends and a middle portion;
b) coupling the two ends of the tensile member to the roof structure such that the tensile member extends along the roof structure;
c) providing a king post tensioning system;
d) positioning the king post tensioning system between the roof structure and the middle portion of the tensile member;
e) tensioning the tensile member; and
f) mounting the solar panel on the roof structure;
wherein the tensile member and the king post tensioning system are configured to be under strain when there are loads on the roof structure caused by mounting the solar panel on the roof structure.

9. The method of claim 8, wherein the tensile member and the king post tensioning system are configured to be under strain when there is a pre-existing dead load on the roof structure prior to mounting the solar panel on the roof structure.

10. The method of claim 8, wherein the step of tensioning the tensile member occurs before mounting the solar panel on the roof structure.

11. The method of claim 8, further comprising ballasting the solar panel on the roof structure.

12. The method of claim 8, further comprising reinforcing the roof structure proximal to the ends of the tensile member.

13. A retrofit kit for strengthening an existing roof structure comprising:
a) a tensile member having two ends and a middle portion;
b) two couplings attached to the ends of the tensile member, the couplings being couplable to the roof structure such that the tensile member extends along the roof structure; and
c) a king post tensioning system having an upper portion connectable to the existing roof structure, and a lower portion connectable to the middle portion of the tensile member.

14. The retrofit kit of claim 13, further comprising additional truss end reinforcing members.

15. The retrofit kit of claim 13, wherein the tensile member and the king post tensioning system are configured to be under strain when there is a pre-existing dead load on the roof structure.

16. The retrofit kit of claim 13, wherein the tensile member is a continuous cable.

17. The retrofit kit of claim 15, wherein the king post tensioning system has a convex lower end shaped to engage the cable.

18. The retrofit kit of claim 15, wherein the lower portion of the king post tensioning system has a channel shaped to receive the cable.

19. The retrofit kit of claim 13, wherein the upper portion of the king post tensioning system is shaped to fit within a gap within the roof structure so as to connect the king post tensioning system to the roof structure.

20. The retrofit kit of claim 13, wherein the couplings include hooks attached to the ends of the tensile member, each of the hooks configured to hook onto the roof structure.
